(19) United States
(12) Patent Application Publication
(10) Pub. No.: US 2023/0319485 A1
(43) Pub. Date: Oct. 5, 2023

(54) MEMS SOUND TRANSDUCER

(71) Applicant: Fraunhofer-Gesellschaft zur Foerderung der angewandten Forschung e.V., Munich (DE)

(72) Inventors: Fabian STOPPEL, Itzehoe (DE); Fabian LOFINK, Itzehoe (DE); Malte Florian NIEKIEL, Itzehoe (DE); Bernhard WAGNER, Itzehoe (DE)

(21) Appl. No.: 18/129,548

(22) Filed: Mar. 31, 2023

(30) Foreign Application Priority Data
Mar. 31, 2022 (DE) 102022203173.3

(51) Int. Cl. H04R 19/02; H04R 7/06; H04R 7/18; B81B 3/00

(52) U.S. Cl. CPC H04R 19/02; H04R 7/06; H04R 7/18; B81B 3/0067; H04R 2201/003; H04R 2440/01; B81B 2203/0127

(57) ABSTRACT

Embodiments of the present disclosure describe an MEMS sound transducer having an actuator and a structure surrounding the actuator, wherein the actuator is separated from the surrounding structure by one or several slits. Furthermore, the sound transducer includes at least one first diaphragm arranged on the actuator along at least one of the one or several slits; and at least one second diaphragm arranged on the surrounding structure along the slit of the one or several slits.

### CROSS-REFERENCE TO RELATED APPLICATION

This application claims priority from German Patent Application No. DE 10 2022 203 173.3, which was filed on Mar. 31, 2022, and is incorporated herein in its entirety by reference.

Embodiments according to the present disclosure relate to MEMS sound transducers with diaphragms. Further embodiments relate to MEMS sound transducers with microstructures for air damping.

### BACKGROUND OF THE INVENTION

MEMS loudspeakers, same as conventional loudspeakers, are based on the displacement of air by stroke movements or bending movements of an actuator. The sound level created therethrough is proportional to the displaced air volume. A configuration of an MEMS loudspeaker with piezoelectrically driven, vertically-moving micro-actuators is illustrated in FIG. 1 (from F. Stoppel, A. Männchen, F. Niekiel, D. Beer, T. Giese, I. Pieper, D. Kaden, S. Grünzig, B. Wagner, Piezoelektrische MEMS-Lautsprecher für In-Ear-Anwendungen, MikroSystem-Technik Kongress 2019, Berlin, 182-185; DE10 2017 208 911).

FIG. 1 shows a schematic illustration of an MEMS loudspeaker 100 in a non-deflected (top) and deflected (bottom) state. The MEMS loudspeaker comprises a chip frame 110, or a substrate, as well as actuators 120 clamped in at the chip frame 110. The actuators are formed in two layers of a layer of piezoelectric PZT (lead zirconate titanate) 130 and a layer of polysilicon 140. Decoupling slits 150 are arranged between the actuators. In the case of deflection (bottom), through the decoupling slits 150, the actuators can move in a manner decoupled from each other.

In the case shown, the sound-generating actuator structure is not configured by an enclosed membrane, but by several actuators 120 separated by means of tight slits 150. However, the MEMS actuator structures that are moved may have Q factors (exaggerations of the oscillation amplitudes) with values in the range of 100. Through this, the sound pressure level generated in the frequency path may have steep resonance peaks that may lead to acoustic distortion (cf. FIG. 2 and FIG. 3).

FIG. 2 shows sound pressure levels (SPL) in dB of the MEMS loudspeaker, measured in an ear simulator in case of different drive voltages with or without an equalizer (EQ) filter across the frequency in Hz. The lower solid line describes a sound pressure level at one volt with an EQ filter, the dotted line describes a sound pressure level and one volt without an EQ filter, and the upper solid line describes a sound pressure level at ten volts with an EQ filter. The sound pressure level at one volt without an EQ filter shows a large peak at slightly more than 8000 Hz. FIG. 2 shows that electronic filters may be used to smooth out the sound pressure level. However, this measure does enable reducing distortions, i.e. harmonic (or nonlinear) distortion of the loudspeaker (cf. FIG. 3).

FIG. 3 shows harmonic distortions in % at an amplitude of 1 V with an EQ filter (corresponds approximately to a SPL of 85 dB) across the frequency in Hz. In FIG. 3, the total harmonic distortion (THD) and portions of individual harmonics of the total harmonic distortion factor (k2, k3, k5) are plotted. The illustrated quantities indicate a ratio of, e.g. undesired, harmonic content in the signal. FIG. 3 shows high peaks of the distortion and the portions of the total harmonic distortion factor in the range of approximately 2000 Hz and in the range of slightly more than 3000 Hz. FIG. 3 shows that EQ filters cannot smooth out these signal distortions.

For example, due to the distortions, it is not possible to use the entire bandwidth of a corresponding MEMS sound transducer. For example, in case of applications in the ultrasound range, sound transducers with a lower Q factor, i.e. a higher bandwidth, are needed. Thus, the transducer may generate short impulses in the pulse-echo method, among others, or may transmit or receive modulated signals in the continuous-wave method.

In existing MEMS sound transducers, the resonances of the actuators cannot be selectively damped. For example, it would be desirable to achieve Q factors in the range of smaller than 5 and/or to fully suppress the resonance peak. Thus, there is a need for an improved approach.

### SUMMARY

According to an embodiment, an MEMS sound transducer comprises: an actuator; a structure surrounding the actuator, wherein the actuator is separated from the surrounding structure by one or several slits; at least one first diaphragm arranged on the actuator along at least one of the one or several slits and extending out of the substrate plane and/or into the substrate plane; and at least one second diaphragm arranged on the surrounding structure along the slit of the one or several slits and extending out of a substrate plane and/or into the substrate plane.

Embodiments according to the present disclosure provide MEMS sound transducers with an actuator and a structure surrounding the actuator, wherein the actuator is separated from the surrounding structure by one or several slits. Furthermore, the MEMS sound transducer comprises at least one first diaphragm arranged on the actuator along at least one of the one or several slits, and at least one second diaphragm arranged on the surrounding structure along the slit of the one or several slits. According to further embodiments, the diaphragms may extend upwards or downwards, i.e. out of the substrate plane and into the substrate plane. In other words, according to embodiments, the first and/or second diaphragm extends out of a lateral main extension direction of the actuator and the surrounding structure, e.g. perpendicularly or essentially perpendicularly. According to other/additional embodiments, the first and/or second diaphragm extends into a lateral main extension direction of the actuator and the surrounding structure, e.g. perpendicularly or essentially perpendicularly.

Furthermore, as a type of diaphragm, the actuator and/or the surrounding structure comprise plate structures that are arranged essentially perpendicularly (e.g. in the context of embodiments perpendicularly means 75° and 105° or 85 and 95° or 89° and 91°) with respect to the actuator, wherein the plate structures are arranged at an edge of the actuator facing the surrounding structure and/or at an edge of the surrounding structure facing the actuator, each opposing the other and/or each opposing the edge of the actuator or the surrounding structure, separated by one or several slits.

Further embodiments according to the present disclosure provide MEMS sound transducers for generating sound with an actuator that is separated from a surrounding structure by one or several slits. In this case, the actuator is configured to perform a relative movement between the actuator and the surrounding structure.

Embodiments according to the present disclosure are based on the core idea that arranging opposing diaphragms, or diaphragms in general, on the side of the actuator and on the side of the surrounding structure enables frequency-dependent signal damping of an MEMS sound transducer. For the relative movement between the actuator and the surrounding structure, a gas, e.g. air (a medium in general), located in the slit between the actuator and the surrounding structure is displaced. This leads to (air) friction which in turn dampens the actuator. This effect is maximized through the elongation of the opposing surfaces formed by the diaphragms. Furthermore, advantageously, “gaping” of the slit is avoided when the actuator is deflected, so that the friction effect is still maintained regardless of the deflection of the actuator.

In embodiments according to the present disclosure, the at least one first diaphragm and the at least one second diaphragm are arranged opposite each another. Advantageous damping properties may be achieve through such an arrangement.

Here, the speed of the gas in the slit depends on the oscillation frequency of the actuator. By appropriately selecting the geometries of the actuator and the surrounding structure, speed-dependent and therefore frequency-dependent damping may be exploited to dampen (or attenuate) certain frequencies of the MEMS sound transducer. Advantageously, this makes it possible to optimize the sound transducer or the acoustical properties.

An MEMS sound transducer may suppress harmonic distortion that cannot be electronically filtered or only with much difficulty (cf. e.g. FIG. 3). In this case, damping depends on the overlapping areas of the actuator and the surrounding structure that move beyond each other by means of the relative movement, as well as on the distance of the opposing areas of the actuator and the surrounding structure. The opposing areas are characterized in that they directly oppose the surrounding structure or the actuator and move past each other in case of a corresponding relative movement. For example, these areas of the diaphragms of the actuator and the surrounding structure may be configured to be parallel to each other and may move past each other in a parallel manner or at least partially parallel manner through the relative movement.

At this point, for the sake of completeness, it is to be noted that, according to embodiments, the first and the second diaphragm may be arranged opposing each other or also overlapping each other, i.e. partially opposing each other. According to further embodiments, the actuator and the surrounding structure oppose each other laterally and/or separated by a slit. According to embodiments, the thickness of the slit and/or the distance between the first and the second diaphragm along a lateral and/or horizontal extension direction essentially remains constant so that e.g., the first and second diaphragms are arranged opposing each other such that they essentially extend in parallel or comprise areas opposing each other in parallel.

To amplify the damping, according to the disclosure, this area may be increased by the use of additional diaphragms, plate structures and/or engaging projections and/or recesses on the actuator and the surrounding structure. Additionally or alternatively, the damping may be amplified by means of a smaller distance of the areas with respect to each other. Examples for such a small distance are less than 10%, less than 5%, or less than 1% of the area or the length of the actuator. For example, if the actuator has a size of 1 centimeter, e.g., the slit has an area of less than 10% of one square centimeter or has a width of less than 1 millimeter. That is, the width of the slit may be either defined as the width or as the width×length.

According to embodiments, in a deflected state, the distance between the first and the second slit along a lateral and/or horizontal extension direction is limited to up to 2.0 times or up to 1.5 times or up to 1.1 times a distance in a non-deflected state. This advantageously maintains the friction effect across the entire movement range of the actuator.

In other words, embodiments according to the present disclosure are based on the idea to integrate additional flow-mechanical structures, such as diaphragms, plate structures, that are used to damp the MEMS sound transducer, e.g. configured as a loudspeaker, by means of a viscose gas flow or air flow. In this case, it is to be noted that the diaphragms may be configured as plate structures.

According to embodiments, e.g., the actuator may perform a relative movement with respect to the surrounding structure. The diaphragm extends at least partially in a direction that extends essentially in parallel to the relative movement.

In embodiments according to the present disclosure, the multitude of diaphragms consist of at least one of a semiconductor, such as silicon, silicon compounds, metals or polymers. This enables simple manufacturing with conventional MEMS manufacturing technologies.

MEMS sound transducers according to the disclosure enable the use of materials with good availability, whose associated manufacturing methods are technically mature, so that a corresponding MEMS sound transducer may be manufactured with low cost and high quality.

In embodiments according to the present disclosure, the MEMS sound transducer is configured to emit a sound signal upon excitation with an electric signal. A configuration according to the disclosure of the MEMS sound transducer as an MEMS loudspeaker makes it possible to solve or at least mitigate problems, e.g., of existing loudspeakers, e.g. with respect to harmonic distortion, due to the multitude of (opposing) diaphragms.

In embodiments according to the present disclosure, the MEMS sound transducer is configured to generate signals in a frequency range of at least 20 Hz and/or up to 20 kHz. Alternatively or additionally, the MEMS sound transducer may be configured as an MEMS ultrasound transducer. An MEMS ultrasound transducer according to the disclosure may be configured to generate signals in a frequency range of at least 20 kHz and/or up to 100 MHz.

The implementation of the MEMS sound transducer in a frequency range of 20 Hz to 20 kHz, or in other words in a frequency range audible for humans, enables the use of the sound transducer in acoustic applications such as in-ear headphones, smartphones or headsets. For example, a high audio quality may be achieved through the use of recesses and projections according to the disclosure. In particular, e.g., even in a case of high frequencies, undesired harmonic distortion may be suppressed. An MEMS ultrasound transducer according to the disclosure may further achieve a high bandwidth through the damping of harmonic distortions for high frequencies so that, e.g. for measurement methods such as the pulse-echo method, short impulses may be generated, or modulated signals may be transmitted for continuous-wave methods.

In embodiments according to the present disclosure, the one or the several slits have a width of less than 20 μm, less than 10 μm, or 5 μm, or in general a width that is in the range of 0.1 μm to 20 μm. For example, the width of the slit may be a width in the lateral direction or in the horizontal direction of the component or the MEMS sound transducer.

Through the width in the range of micrometers, corresponding MEMS sound transducers may be built with little space requirement, on the other hand, sufficient decoupling of the sound pressures in front of and/or behind the actuator may be enabled, so that a defined acoustic sound pressure may be generated. In addition, corresponding dimensioning of the slits may be advantageous for the frequency-dependent damping, e.g. for suppressing the harmonic distortion.

According to embodiments, the actuator is configured as a bending actuator. In this case, according to embodiments, a free end of the bending actuator and/or one or several sides of the bending actuator (between the clamped end and the free end) may comprise the first diaphragm. According to further embodiments, the actuator may be configured as a stroke actuator. According to embodiments, one side or several sides of the stroke actuator comprise the first diaphragm.

### BRIEF DESCRIPTION OF THE DRAWINGS

Embodiments of the present invention will be detailed subsequently referring to the appended drawings, in which:

FIG. 1 shows a schematic illustration of an MEMS loudspeaker in a non-deflected (top) and deflected (bottom) state;

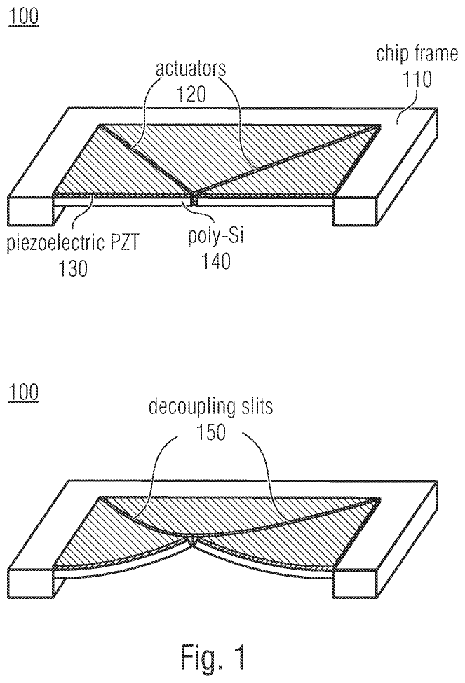

FIG. 2 shows sound pressure levels (SPL) in dB of the MEMS loudspeaker, measured in an ear simulator at different drive voltages with or without an equalizer (EQ) filter across the frequency in Hz;

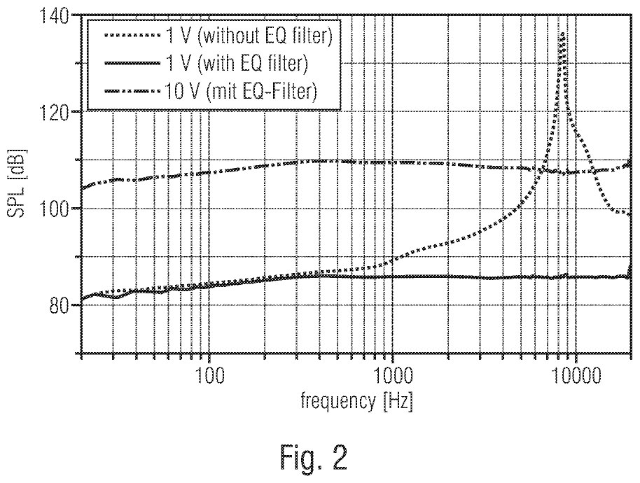

FIG. 3 shows harmonic distortions in % at an amplitude of 1 V with an EQ filter (corresponds approximately to a SPL of 85 dB) across the frequency in Hz;

FIG. 4 shows an example for viscose air damping of a plate upon parallel movement close to a fixed plate element;

FIG. 5 shows a schematic illustration of an MEMS sound transducer according to a base embodiment of the present invention; and

FIG. 6 shows a schematic side view of an MEMS sound transducer according to an embodiment of the present disclosures with diaphragms, exemplarily configured as plate structures, at the edge of the actuator and the surrounding structure.

### DETAILED DESCRIPTION OF THE INVENTION

Before embodiments of the present disclosure are subsequently described in detail on the basis of the drawings, it is to be noted that functionally identical elements, objects and/or structures, or elements, objects and/or structures with the same effect are provided in the different drawings with the same or similar reference numerals so that the description of these elements illustrated in different embodiments is interchangeable, or may be applied to each other.

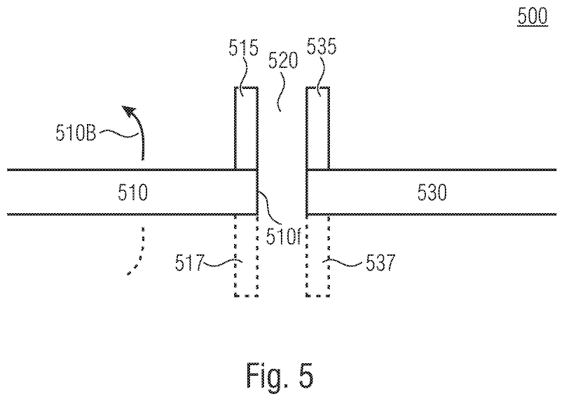

FIG. 5 shows a schematic illustration of an MEMS sound transducer 500 with an actuator 510, here a bending actuator. A surrounding structure 530 is arranged opposite to the actuator 510. For example, the actuator 510 and the surrounding structure 530 may be arranged in a common plane (substrate plane), or may together define a main extension direction of the MEMS sound transducer 500. The MEMS actuator 510 and the surrounding structure 530 are separated by a slit 520. In this embodiment, the actuator 510 and the surrounding structure 530 comprise a diaphragm of an MEMS actuator 515 and 535, respectively. The diaphragm 515 and the diaphragm 535 extend out of the plane defined by the elements 510 and 530, e.g. perpendicularly towards the top, each at the edge, i.e. directly adjacent to the slit 520. In other words, this means that the diaphragms 515 and 535 extend along the slit 520 and oppose each other or partially oppose each other. In this embodiment, the diaphragms 515 and 535 extend out of the substrate plane, i.e. towards the sound emission direction of the actuator 510. The movement direction of the sound actuator 510 (ultrasound actuator, sound actuator) is here indicated with the arrow 510b.

According to further embodiments, additional diaphragms 517 and 537 extending into the substrate plane, i.e. opposite the emission direction, may be provided. These diaphragms 517 and 537 represent the extension to the elements 515 and 535, respectively, so that a type of plate is configured in the edge region at the ends adjacent to the slit (free end of the actuator 510 and opposing end of the surrounding structure 530, respectively). The opposing areas on the two sides of the slit 520 are maximized through the diaphragms 515 and 535, or through the diaphragm combination 515 and 517 and 535 and 537. This creates two effects:
1. Regardless of the deflection movement 510b of the actuator 510, there is no gaping of the slit 520. Thus, in other words, sealing of the area in front of the actuator 510 and the area behind the actuator 510 may be achieved by increased viscosity losses without limiting the movability of the actuator 510.
2. Increased air friction is created through the at most opposing areas of the diaphragms 515 and 535 or 515 and 517 and 535 and 537, which further maximizes this sealing effect.

In the following, the idea will be described in more detail on the basis of plate structures. The plate structures may be examples for projections and/or diaphragms on the actuator or the surrounding structure. Furthermore, plate structures may be examples for recesses, or for the structure, or in other words for the remaining material surrounding a recess or defining the recess.

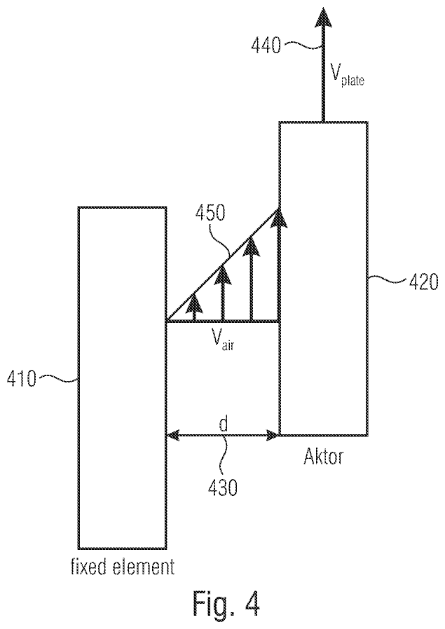

This may exploit the fact that there is a friction force between a fixed planar plate and a plate moving past the same with the speed v (cf. FIG. 4).

FIG. 4 shows an example for viscose air damping of a plate upon parallel movement close to a fixed plate element, e.g. wherein close to refers to the distance of the plates with respect to the plate area. FIG. 4 shows a schematic side view of a plate 410 of the surrounding structure comprising a fixed element and a plate 420 of the actuator. In general, e.g., the fixed element may be an immovable part of the surrounding structure, or may be the surrounding structure itself. For example, the fixed element may be a substrate. The two plates are arranged spaced apart from each other with a distance d 430. The plate 420 of the actuator comprises a relative speed vₚₗₐₜₑ 440 so that it moves in parallel to the plate 410 of the surrounding structure and past the same. A speed distribution 450 of the speed of the air vₐᵢᵣ of the gap between the two plates 410, 420 is illustrated between the plates 410, 420.

If the distance d 430 of the plates is small with respect to the plate dimensions, the speed of the air from the fixed plate 410 to the moving plate 420 may increase linearly from zero to the value v. Thus, the air layers between the plates may slide past each other with different speeds. This may result in a frictional force Fᵣ that may be calculated with Newton's law of friction:

Fᵣ=ηAv/d.

Here, A is the overlap of the plate areas, d is the plate distance 430, v is the speed 440 of the moving plate (vₚₗₐₜₑ) and η is the viscosity of the air. The friction force is proportional to the speed 440 of the moving plate and forms a damping element in the differential equation of the plate movement or oscillation.

Accordingly, through an implementation according to the disclosure of the actuator and the surrounding structure with recesses and/or projections and/or diaphragms, or with plate structures, e.g. as projections, an MEMS sound transducer that enables desired damping of certain frequencies by adapting the overlapping area and the distance of the relatively moving surfaces of the actuator and the surrounding structure may be provided.

Here, it is to be noted that, instead of the diaphragms 515 or 535 extending out of the substrate, the diaphragms 515 and 537 extending into the substrate end may be provided. According to embodiments, the diaphragms 515, 517, 535, 537 are applied as separate elements or are part of the structures 510 and 530, for example. Regardless of the particular production, the diaphragms 515 and 517 follow the movement of the free end 510f of the actuator 510 since they are directly adjacent to the free end 510f. Analogously hereto, in case of the diaphragms 535 and 537, there is no movement relative to the structure 530.

Here, it is to be noted that, e.g., the diaphragm 537 may also be formed as a part of the substrate and does not necessarily have to be applied as a separate element. In general, the diaphragms 515, 535 may have a height (out of the substrate plane) and/or a depth (into the substrate plane) of at least 10% or 50% of the length (lateral dimension) of the actuator 510, for example.

According to embodiments, the areas of the diaphragms 515 facing the slit 520, the area of the free end 510f as well as the optional area of the diaphragm 517 form a common surface, i.e. a flat or planar surface. Analogously hereto, e.g., the area facing the slit 520 of the diaphragm 535, the optional diaphragm 537 and the front face of the surrounding structure 530 also form a common planar surface.

According to a further embodiment, the diaphragms 515 and 537 may extend upwards, e.g. perpendicularly, i.e. approximately in an angle between 88° and 92°. For example, when assuming a bending actuator 510b, the diaphragms may also have a progression that is adapted to the movement 510b, e.g. that is configured to be curved. Analogously hereto, e.g., the diaphragms 517 and 537 extend perpendicularly, i.e. in a range between 88° and 92°, into the substrate plane. Here, a curved progression would also be conceivable.

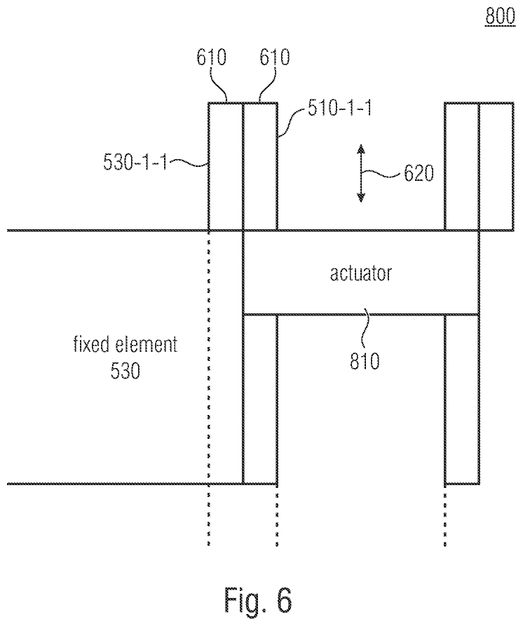

Subsequently, the diaphragms are described as a plate structure with respect to FIG. 6.

FIG. 6 shows a schematic side view of an MEMS sound transducer according to an embodiment of the present disclosure, with diaphragms, exemplarily configured as plate structures, at the edge of the actuator and the surrounding structure, comprising a fixed element. FIG. 6 shows an MEMS sound transducer 600 with an actuator 510 separated from a surrounding structure 530 by one of several slits 520, wherein the surrounding structure 530 comprises a fixed element. The actuator 510 is configured to perform a relative movement 620 between the actuator 510 and the surrounding structure 530. The actuator 510 and the surrounding structure 530 comprise diaphragms (first diaphragms 510-1-1 on the actuator and second diaphragms 530-1-1 on the surrounding structure) in the form of plate structures, or plates 610, arranged perpendicularly to the actuator 510, wherein the plate structures 510-1-1 are arranged at an edge of the actuator facing the surrounding structure, and the plate structures 530-1-1 are arranged at an edge of the surrounding structure facing the actuator, each opposing one another or each opposing the edge of the actuator or the surrounding structure, separated by one of several slits 520.

As is illustrated in FIG. 6, diaphragms may be arranged to extend into or out of a common plane of the actuator and the surrounding structure. Thus, the diaphragms may have an extension direction, e.g., that is parallel to an emission direction of the actuator. The diaphragms may also be arranged on the actuator and/or the surrounding structure in the emission direction of the sound generated by the actuator and/or opposite to this emission direction. Simply put, the at least one diaphragm may be arranged on a top and/or a bottom side of the actuator. FIG. 6 illustrates second diaphragms of the surrounding structure only on one side, e.g. the top side of the surrounding structure, however, second diaphragms may also be arranged on a bottom side of the surrounding structure opposing the top side.

The top or bottom sides of the actuator or the surrounding structure may here each be one of the sides whose associated normal vector is at least approximately parallel to a movement direction of a relative movement between the actuator and the surrounding structure. Here, the actuator 510 and the surrounding structure 530 may have a multitude of diaphragms that may each be arranged above and/or below the actuator and/or the surrounding structure. Here, an extension direction of the diaphragms may be at least approximately perpendicular to a common plane of the actuator and the surrounding structure, in which the actuator and the surrounding structure laterally oppose each other. As is shown in FIG. 6, the actuator 510 may optionally be configured as a stroke actuator. However, further embodiments include corresponding bending actuators with associated diaphragms. Furthermore, e.g., the top side may be a side facing away from the substrate, and the bottom side may be a side facing a substrate, for example.

In other words, FIG. 6 shows plate structures 610 at the edge of the actuator 510 and the surrounding structure 530 comprising a fixed element. In this embodiment, the plate structures are arranged at the edge on the actuator 510 and/or underneath the actuator 510. In this example, the actuator 510 is configured as a stroke actuator. Plate structures 610, e.g. damping structures in the form of plates, are formed at a close distance to the actuator on the laterally opposing fixed element (e.g. chip frame).

The overlapping area between the actuator 510 and the surrounding structure 530 may be increased by the diaphragms or plate structures 510-1-1 and 530-1-1 so as to amplify a viscose gas friction and, accordingly, damping of certain resonance frequencies. Here, the diaphragms or plate structures 610 may be configured as projections, wherein the gap between two plates, e.g. of the actuator, may be configured as a recess.

In other words—to technologically implement the above-described damping—diaphragms, or vertical plate structures, 610 may be arranged on the vertically moving actuator 510 of the MEMS sound transducer, or the loudspeaker, and, e.g., an opposing fixed element may be arranged on the opposing surrounding structure 530. Through these flow-mechanical structures, the actuator movement may be damped by the viscose gas flow, e.g. the air flow. From the equation for the friction force, it can be seen that damping is maximized if largest possible areas are arranged in the closest possible distance. This means that damping structures, e.g. plate structures 610, with a high aspect ratio may be advantageous. The overlapping area of the plate 610 may also be increased by implementing the plate as engaging comb structures with a multitude of fingers.

Embodiments according to the present disclosure provide MEMS loudspeakers or MEMS ultrasound speakers with viscose air damping, characterized in that microstructures with a high aspect range ratio that move relatively to each other at a close distance are arranged on a vertically moving actuator and on a vertically or laterally opposing fixed element or a surrounding structure, thereby damping the actuator movement by means of the air flow in a viscose manner.

According to embodiments, the actuator is configured to move out of a substrate plane or to move into the substrate plane or to oscillate out of and into the same. For example, the substrate plane is formed by the main extension direction of the substrate having integrated thereinto the MEMS component. The substrate plane has at least one main surface, wherein the movement direction of the oscillator is arranged to be perpendicular or essentially perpendicular (i.e. in the range of −85° to +95°).

According to embodiments, the bending elements extend out of the substrate plane or into the substrate plane. According to embodiments, the two diaphragms (one diaphragm on the actuator side and one diaphragm on the surrounding structure) are opposite each other, i.e. directly separated from each other by the slit. The two diaphragms create two parallel, or essentially parallel, surfaces that are opposite each other at the slit.

Further embodiments according to the present disclosure provide MEMS loudspeakers with an piezoelectric or magnetic or electrostatic drive.

Further embodiments according to the disclosure comprise an aspect ratio of the microstructures with respect to height/width>10 and/or height of the microstructures>50 μm.

In embodiments according to the present disclosure, the engaging elements are separated by one or several slits such that the engaging elements comprise a damping function, that is e.g. the above described damping, upon a relative movement between the actuator and the surrounding structure.

In further embodiments according to the present disclosure, the surrounding structure is formed by a substrate. By forming projections and recesses directly on the substrate, e.g., a particularly simple and cost efficient implementation of an MEMS sound transducer according to the present disclosure may be implemented. For example, the actuator may be etched directly out of the substrate and may be provided with projections and recesses that engage in corresponding structures of the substrate.

In embodiments according to the present disclosure, the multitude of recesses and projections are configured as microstructures with an aspect ratio of height/width of more than 5, wherein the height is a height orthogonal to a surface of the actuator or the surrounding structure on which the projection is arranged. In this case, the width is a width parallel to the surface of the actuator or the surrounding structure on which the projection is arranged.

The viscose friction and, therefore, the damping may be amplified by means of a high aspect ratio. Through the corresponding configuration of the recesses and projections, the area between the actuator and the surrounding structure contributing to the friction may be increased, e.g. for a desired frequency range, and, at the same time, a small distance of the elements with respect to each other may be realized to further increase the damping. Here, it is to be noted that the aspect ratio does not only apply for heights of structures, but analogously also to corresponding depths, e.g. in the case of recesses. Furthermore, recesses and/or projections may comprise corresponding heights or depths, e.g. in particular orthogonal to the movement of the actuator, wherein the width of the recess or structure may be orientated in parallel to the movement direction.

In embodiments according to the present disclosure, the actuator comprises a piezoelectric or magnetic or electrostatic drive. Alternatively or additionally, the actuator may be formed by a bending transducer. For example, the piezoelectric drive may be carried out advantageously by means of integrated piezoelectric layers, e.g. for applications as an MEMS loudspeaker. In this case, piezoelectric drives may have advantages with respect to short response time, high accelerations, and low energy demands. However, embodiments according to the present disclosure are not limited to piezoelectric drives, but enable the use of drive concepts, e.g., that are particularly advantageous for an application, e.g. electrostatic or magnetic concepts or principles. For example, the implementation of the actuator as a piezoelectric bending transducer, or bending actuator, may have advantages with respect to the actuator travel and actuator force as well as the reliability.

In embodiments according to the present disclosure, the projections of the multitude of projections have a height of more than 50 μm, wherein the height is a height orthogonal to a surface of the actuator or the surrounding structure on which the respective projection is arranged.

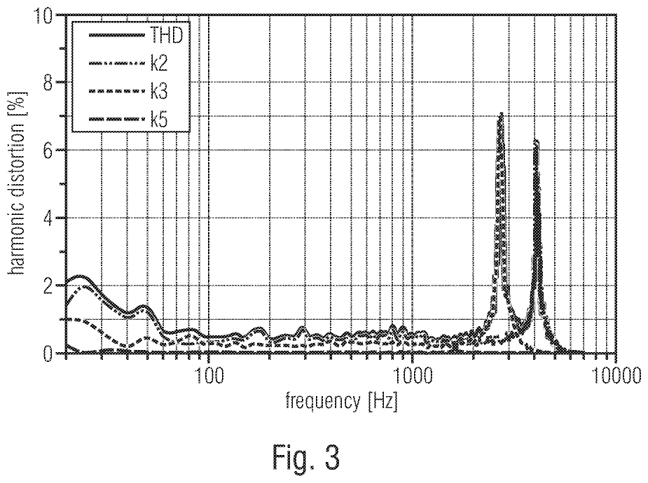

The implementation according to the present disclosure of the height of the projections enables sufficient damping so as to at least partially suppress undesired harmonic distortion (cf. FIG. 3). For example, this may achieve an advantageous aspect ratio of projections and corresponding recesses, so that the viscose gas friction enables the desired damping.

Further embodiments according to the present disclosure additionally comprise damping structures, e.g. recesses and projections, at the edge of the actuator and the surrounding structure and/or the fixed element, e.g. in the form of plates or comb structures.

Further embodiments according to the present disclosure additionally comprise columns or cone structures on the actuator area, hole or slit structures on the surrounding structure, e.g. the fixed element.

Further embodiments according to the present disclosure comprise damping structures made of silicon, Si compounds, metals or polymers.

Further embodiments according to the present disclosure provide MEMS loudspeakers with a frequency range of 20 Hz-20 kHz.

Further embodiments according to the present disclosure comprise MEMS ultrasound transducers with a frequency range of 20 kHz to 100 MHz.

Embodiments according to the present disclosure provide MEMS sound transducers or loudspeakers for in-ear headphones and/or free field loudspeakers for applications close to the ear.

In general, embodiments according to the present disclosure provide that the loudspeaker damping may be integrated directly into the MEMS structure, e.g. the MEMS sound transducer, and may be adjusted through the arrangement and dimensioning of the microstructures. This may provide a decisive advantage of MEMS sound transducers according to the disclosure, e.g., with respect to the installation space and functionality, e.g. for mobile applications.

All lists of materials, environmental influences, electrical properties, and optical properties stated herein are considered to be exemplary and are not limiting in any way.

Even though some aspects have been described within the context of a device, it is understood that said aspects also represent a description of the corresponding method, so that a block or a structural component of a device is also to be understood as a corresponding method step or as a feature of a method step. By analogy therewith, aspects that have been described within the context of or as a method step also represent a description of a corresponding block or detail or feature of a corresponding device. Some or all of the method steps may be performed while using a hardware device, such as a microprocessor, a programmable computer or an electronic circuit. In some embodiments, some or several of the most important method steps may be performed by such a device.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. MEMS sound transducer, comprising:
an actuator;
a structure surrounding the actuator, wherein the actuator is separated from the surrounding structure by one or several slits;
at least one first diaphragm arranged on the actuator along at least one of the one or several slits and extending out of the substrate plane and/or into the substrate plane; and
at least one second diaphragm arranged on the surrounding structure along the slit of the one or several slits and extending out of a substrate plane and/or into the substrate plane.

2. MEMS sound transducer according to claim 1, wherein the first and/or the second diaphragm extends out of a lateral main extension direction of the actuator and the surrounding structure; and/or
wherein the first and/or the second diaphragm extends essentially perpendicularly out of a lateral main extension direction of the actuator and the surrounding structure.

3. MEMS sound transducer according to claim 1, wherein the first and/or the second diaphragm extends into a lateral main extension direction of the actuator and the surrounding structure; or
wherein the first and/or the second diaphragm extends essentially perpendicularly into a lateral main extension direction of the actuator and the surrounding structure.

4. MEMS sound transducer according to claim 2, wherein essentially perpendicularly comprises an angle between 75°-105° and in particular between 85°-95°.

5. MEMS sound transducer according to claim 1, wherein the actuator is configured to perform a relative movement between the actuator and the surrounding structure.

6. MEMS sound transducer according to claim 5, wherein the first and the second diaphragm extend at least partially in a direction that is essentially parallel to the relative movement.

7. MEMS sound transducer according to claim 1, wherein the first diaphragm and the second diaphragm are arranged opposing each other or overlapping each other.

8. MEMS sound transducer according to claim 1, wherein the actuator and the surrounding structure oppose each other laterally and/or separated by the slit.

9. MEMS sound transducer according to claim 1, wherein the thickness of the slit and/or the distance between the first and the second diaphragm along a lateral and/or horizontal extension direction remains essentially constant; and/or wherein the first and the second diaphragm extend essentially in parallel and/or comprise parallel areas opposing each other.

10. MEMS sound transducer according to claim 1, wherein, in a deflected state, the distance between the first and the second diaphragm along a lateral and/or horizontal extension direction corresponds to up to 2.0 times or up to 1.5 times or up to 1.1 times a distance in a non-deflected state.

11. MEMS sound transducer according to claim 1, wherein the actuator is configured as a bending actuator.

12. MEMS sound transducer according to claim 11, wherein at least one free end of the bending actuator and/or one or several sides of the bending actuator between a clamped end and a free end comprise the first diaphragm.

13. MEMS sound transducer according to claim 1, wherein the actuator is configured as a stroke actuator.

14. MEMS sound transducer according to claim 13, wherein the at least one side of the stroke actuator and at least one or several sides of the stroke actuator comprise the first diaphragm.

15. MEMS sound transducer according to claim 1, wherein the actuator is configured to emit a sound signal on the basis of an electric signal.
